(19) United States
(12) Patent Application Publication
(10) Pub. No.: US 2025/0324902 A1
(43) Pub. Date: Oct. 16, 2025

(54) DISPLAY DEVICE AND ELECTRONIC DEVICE INCLUDING THE SAME

(71) Applicant: Samsung Display Co., Ltd., Yongin-Si (KR)

(72) Inventors: DASOM GU, Yongin-si (KR); KYUNGTAE KIM, Yongin-si (KR); DOHOON KIM, Yongin-si (KR); Byungcheol Ahn, Yongin-si (KR); SUNGGUK AN, Yongin-si (KR)

(21) Appl. No.: 19/073,003

(22) Filed: Mar. 7, 2025

(30) Foreign Application Priority Data
Apr. 16, 2024 (KR) 10-2024-0050782

(51) Int. Cl. H10K 77/10; H10K 59/80; H10K 102/00

(52) U.S. Cl. CPC H10K 77/111; H10K 59/873; H10K 2102/311; H10K 2102/351

(57) ABSTRACT

A display device includes: a display panel including a foldable area having flexibility and a non-folding area adjacent to the foldable area, a cover window on a first side of the display panel, and a barrier layer on a second side of the display panel opposite to the first side and including an elastomer. A tensile modulus of the barrier layer is in a range from about 0.7 Gpa to about 1.5 Gpa at −20° C.

### CROSS-REFERENCE TO RELATED APPLICATION

This application claims priority to and benefits of Korean Patent Application No. 10.2024-0050782 under 35 U.S.C. § 119, filed on Apr. 16, 2024 in the Korean Intellectual Property Office (KIPO), the entire contents of which are hereby incorporated by reference.

### BACKGROUND

### Technical Field

Embodiments disclosed herein generally relate to a display device. More particularly, embodiments relate to a foldable display device.

### Description of the Related Art

Display devices, as media for communication of information to and from users, have become critical for many technologies. Accordingly, the use of display devices such as liquid crystal display devices, organic light emitting display devices, plasma display devices, and the like is increasing.

Flexible display devices that can be transformed into various shapes have been developed. Unlike a flat panel display, a flexible display device may be folded, bent, or rolled like paper. Such flexible display devices are easy to carry and may be more convenient for users. Recently, among flexible display devices, foldable display devices have been in the spotlight. A foldable display device may be repeatedly folded and unfolded.

### SUMMARY

Embodiments disclosed herein may provide a display device having improved reliability.

A display device according to an embodiment of the present disclosure may include a display panel including a foldable area having flexibility and a non-folding area adjacent to the foldable area, a cover window on a first side of the display panel, and a barrier layer on a second side of the display panel opposite to the first side and including an elastomer. A tensile modulus of the barrier layer may be in a range from about 0.7 Gpa to about 1.5 Gpa at −20° C.

In an embodiment, the tensile modulus of the barrier layer may be in a range from about 0.4 Gpa to about 1 Gpa at room temperature.

In an embodiment, the tensile modulus of the barrier layer at room temperature may be in a range from about 25% to about 60% of the tensile modulus at −20° C.

In an embodiment, the elastomer may include at least one material selected from a group consisting of thermoplastic polyurethane (TPU), polyurethane (PU), polyether block amide (PEBA), acrylonitrile-butadiene rubber (NBR), ethylene-propylene rubber (EPDM), silicone rubber, epoxy material, and polyester block copolymer.

In an embodiment, the barrier layer may include polyether block amide (PEBA).

In an embodiment, a thickness of the barrier layer may be in a range from about 25 micrometers (μm) to about 150 micrometers (μm).

In an embodiment, the display device may further include a support plate under the barrier layer and facing the second side of the display panel.

In an embodiment, the support plate may include metal or alloy.

In an embodiment, the support plate may include carbon fiber reinforced plastic (CFRP) or glass fiber reinforced plastic (GFRP).

In an embodiment, the support plate may include a stretchable portion overlapping the foldable area.

In an embodiment, a plurality of openings spaced apart from each other may be defined in the stretchable portion.

In an embodiment, each of the openings may have a shape extending in a first direction, and the openings may be arranged along the first direction and a second direction that differs from the first direction.

In an embodiment, the display device may further include a panel protective film between the display panel and the barrier layer, and including flexible plastic, a first adhesive member attaching the panel protective film and the barrier layer, and a second adhesive member attaching the barrier layer and the support plate.

In an embodiment, the second adhesive member may overlap the foldable area and the non-foldable area.

In an embodiment, the second adhesive member may not overlap the foldable area and may overlap the non-folding area.

A display device according to an embodiment of the present disclosure may include a display panel including a foldable area having flexibility and a non-folding area adjacent to the foldable area, a cover window on a first side of the display panel, a barrier layer on a second side of the display panel opposite to the first side and including an elastomer, and a support plate under the barrier layer, facing the second side of the display panel, and including a stretchable portion overlapping the foldable area. A tensile modulus of the barrier layer may be in a range from about 0.7 Gpa to about 1.5 Gpa at −20° C. and the tensile modulus of the barrier layer may be in a range from about 0.4 Gpa to about 1 Gpa at room temperature.

In an embodiment, the elastomer may include at least one material selected from a group consisting of thermoplastic polyurethane (TPU), polyurethane (PU), polyether block amide (PEBA), acrylonitrile-butadiene rubber (NBR), ethylene-propylene rubber (EPDM), silicone rubber, epoxy material, and polyester block copolymer.

In an embodiment, a thickness of the barrier layer may be in a range from about 25 micrometers (μm) to about 150 micrometers (μm).

In an embodiment, the support plate may include metal or alloy.

In an embodiment, the display device may further include a panel protective film between the display panel and the barrier layer, and including flexible plastic, a first adhesive member attaching the panel protective film and the barrier layer, and a second adhesive member attaching the barrier layer and the support plate.

An electronic device according to an embodiment of the present disclosure may include a display device and a processor which controls the display device, the display device includes: a display panel including a foldable area having flexibility and a non-folding area adjacent to the foldable area, a cover window on a first side of the display panel, and a barrier layer on a second side of the display panel opposite to the first side and including an elastomer. A tensile modulus of the barrier layer may be in a range from about 0.7 Gpa to about 1.5 Gpa at −20° C.

A display device according to an embodiment of the present disclosure may include a display panel including a foldable area having flexibility and a non-folded area adjacent to the foldable area, and a barrier layer disposed under the display panel and including an elastomer. A tensile modulus of the barrier layer may be in a first predetermined range at low temperature (−20° C.), and the tensile modulus of the barrier layer may be in a second predetermined range at room temperature. Accordingly, the reliability of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view showing a display device according to an embodiment of the present disclosure.

FIGS. 2 and 3 are cross-sectional views showing the display device of FIG. 1 in folded states.

FIG. 4 is a cross-sectional view taken along line I-I′ of FIG. 1.

FIG. 5 is a plan view showing a support member of FIG. 4.

FIG. 6 is an enlarged cross-sectional view of area A of FIG. 4.

FIG. 7 is a block diagram illustrating an electronic device according to an embodiment of the present disclosure.

### DETAILED DESCRIPTION OF THE EMBODIMENTS

Hereinafter, display devices according to example embodiments of the present disclosure are described in detail with reference to the accompanying drawings. The same reference numerals may be used in the various drawings to identify the same components, and redundant descriptions of the same components may be omitted below.

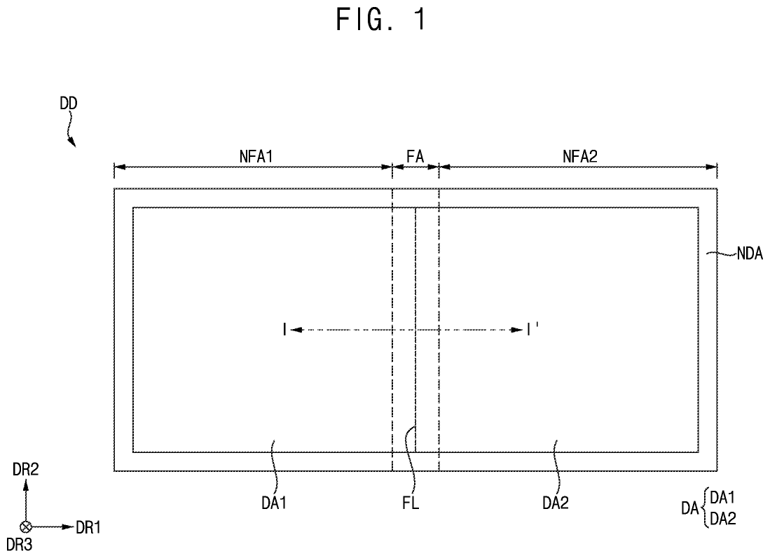

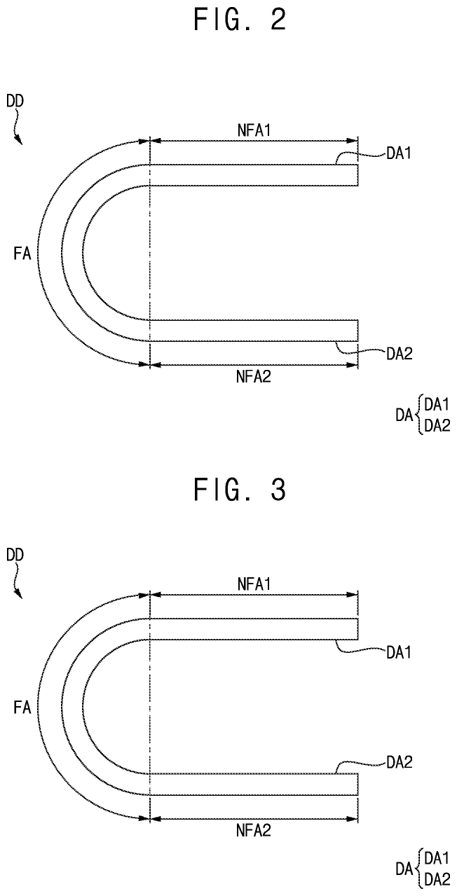

FIG. 1 is a plan view of a display device DD according to an embodiment of the present disclosure In this specification, a first direction DR1 and a second direction DR2 may define a plane of the plan view of FIG. 1. The second direction and DR2 may differ from the first direction. For example, the second direction DR2 may be perpendicular to the first direction DR1. In addition, a third direction DR3 may be perpendicular to the plane that the first direction DR1 and the second direction DR2 define. FIGS. 2 and 3 are cross-sectional views showing the display device DD of FIG. 1 in respective folded states.

Referring to FIGS. 1, 2, and 3, the display device DD according to an embodiment of the present disclosure may be partitioned into a display area DA and a non-display area NDA. The non-display area NDA may be located around the display area DA. For example, the non-display area NDA may surround at least a portion of the display area DA. The display area DA may be an area that can display an image, e.g., by generating light or adjusting the transmittance of light provided from an external light source. The non-display area NDA may be an area that does not display images.

At least a portion of the display device DD may be flexible, and the display device DD may be folded at a flexible portion (i.e., a foldable area FA). That is, the display area DA may include the foldable area FA so that an external force can bend the foldable area FA so as to fold the display device DD. First and second non-foldable areas NFA1 and NFA2 may be adjacent to at least one side of the foldable area, and the first and second non-foldable areas NFA1 and NFA1 do not fold during normal use of the display device DD. For example, the foldable area FA may have a folding line FL extending along the second direction DR2. Here, the area that does not fold is referred to as the non-folding area, but this is for convenience of explanation. The expression “non-folding” refers not only to the case where the non-folding area is rigid due to lack of flexibility, but also to the case where the non-folding area is flexible but does not fold because the non-folding area has less flexibility than the foldable area.

The display area DA may include a first display area DA1 and a second display area DA2. Specifically, the first display area DA1 and the second display area DA2 may be adjacent to each other in the second direction DR2. The first display area DA1 and the second display area DA2 may be continuously connected to substantially form one display area DA. When the display area DA is folded along the folding line FL, as shown in FIG. 2, the first display area DA1 and the second display area DA2 may have an out-folding structure in which the first display area DA1 and the second display area DA2 are disposed on the outside of the fold. Alternatively, when the display area DA is folded along the folding line FL, as shown in FIG. 3, the display device DD may have an in-folding structure such that the first display area DA1 and the second display area DA2 face each other.

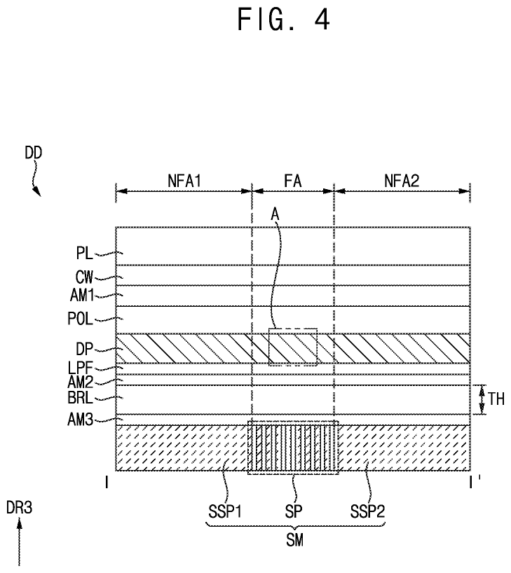

FIG. 1 shows an embodiment of the display device DD having one foldable area FA, but the display device DD according to an embodiment of the present disclosure is not limited to having one foldable area FA. For example, the display device DD may be folded multiple times or may have multiple foldable areas, e.g., to implement a rollable display device. FIG. 4 is a cross-sectional view taken along line I-I′ of FIG. 1.

Referring to FIGS. 1 and 4, the display device DD according to an embodiment of the present disclosure may include a display panel DP, a polarizing member POL, a cover window CW, a window protective layer PL, first, second, and third adhesive members AM1, AM2, and AM3, a panel protective film LPF, a barrier layer BRL, and a support plate SM.

The polarizing member POL may be on the display panel DP. The display panel DP may include a plurality of pixels that generate light, e.g., to display an image. The polarizing member POL may block external light, which is incident on the display panel DP from the outside, and may thereby reduce external light reflection from the display panel DP.

The cover window CW may be on the polarizing member POL. The cover window CW may be on a first side of the display panel DP. The cover window CW may protect the display panel DP. The cover window CW may have a transparent portion corresponding to the display area DA. The cover window CW may include a polymer material, a thin glass film, or the like to enable bending.

In one embodiment, the cover window CW may include ultra-thin tempered glass (UTG). The ultra-thin tempered glass may be strengthened and have a predetermined internal stress profile. The strengthening may allow the ultra-thin tempered glass to better prevent the occurrence of cracks, propagation of cracks, and breakage due to external impacts. The ultra-thin tempered glass may have various stresses in each area through a strengthening process.

In an embodiment, the ultra-thin tempered glass of the cover window CW may be thin film glass that has been chemically strengthened. However, embodiments of the present disclosure are not necessarily limited to this, and the ultra-thin tempered glass of the cover window CW may be thin film glass that has been thermally strengthened.

When glass is composed of an ultra-thin film or a thin film, the glass may be flexible and may have characteristics that permit the glass to be bent, folded, or rolled. For example, the cover window CW may include glass such as soda lime glass, alkali alumino silicate glass, borosilicate glass, lithium alumina silicate glass, and the like. These can be used alone or in combination with each other. However, embodiments of the present disclosure are not necessarily limited thereto, and the cover window CW may include various types of glass.

The first adhesive member AM1 may be between the polarizing member POL and the cover window CW. The first adhesive member AM1 may attach the polarizing member POL and the cover window CW to each other. The first adhesive member AM1 may include, for example, an optical clear adhesive (OCA), a pressure sensitive adhesive (PSA), a photocurable resin, a thermosetting resin, or the like. These can be used alone or in combination with each other. Preferably, the first adhesive member AM1 may include the pressure sensitive adhesive.

The window protective layer PL may be on the cover window CW. The window protective layer PL may perform at least one of the functions of preventing the cover window CW from scattering, absorbing shock, preventing scratches, preventing fingerprints, and preventing glare. The window protective layer PL may include transparent polymer films such as a transparent polymer film. For example, the window protective layer PL may include epoxy resin, polyurethane, polyester, polyethylene terephthalate, polyethylene naphthalate, polyimide, polyarylate, polycarbonate, polymethyl methacrylate, ethyl vinyl acetate, polyamide resin, and the like. These can be used alone or in combination with each other.

The panel protective film LPF may be under the display panel DP. The panel protective film LPF may overlap the foldable area FA and the non-folding areas NFA1 and NFA2. The panel protective film LPF may protect the bottom of the display panel DP. The panel protective film LPF may include a flexible plastic material. For example, the panel protective film LPF may include polyethylene terephthalate. However, embodiments of the present disclosure are not necessarily limited thereto.

The barrier layer BRL may be under the display panel DP. The barrier layer BRL may be on a second side of the display panel DP opposite to the first side. The barrier layer BRL may increase resistance to compressive force due to external pressure. In addition, the barrier layer BRL may serve to prevent deformation of the display panel DP.

In an embodiment, the barrier layer BRL may include an elastomer. For example, the elastomer may include thermoplastic polyurethane (TPU), polyurethane (PU), polyether block amide (PEBA), acrylonitrile-butadiene rubber (NBR), ethylene-propylene rubber (EPDM), silicone rubber, epoxy material, polyester block copolymer, and the like. These can be used alone or in combination with each other. In one embodiment, the barrier layer BRL may include polyether block amide (PEBA).

In an embodiment, the tensile modulus of the barrier layer BRL may be in a range from about 0.7 Gpa to about 1.5 Gpa at low temperature (e.g., about −20° C.). When the tensile modulus of the barrier layer BRL is less than about 0.7 Gpa at the low temperature, buckling of components disposed under the display panel DP may increase. If the tensile modulus of the barrier layer BRL exceeds about 1.5 Gpa at the low temperature, cracks may occur in the window protective layer PL, and the repulsive force or the resistance against folding of the display device DD may increase.

In an embodiment, the tensile modulus of the barrier layer BRL may be in a range from about 0.4 Gpa to about 1 Gpa at room temperature (i.e., about 25° C.). When the tensile modulus of the barrier layer is less than about 0.4 Gpa at room temperature, buckling of components disposed under the display panel DP may increase. When the tensile modulus of the barrier layer BRL exceeds about 1 Gpa at room temperature, cracks may occur in the window protective layer PL, and the repulsive force or the resistance against folding of the display device DD may increase. In another embodiment, the tensile modulus of the barrier layer BRL at the room temperature may be in a range from about 25% to about 60% of the tensile modulus at the low temperature.

In an embodiment, a thickness TH of the barrier layer BRL may be in a range from about 25 micrometers (μm) to about 150 micrometers (μm). Preferably, the thickness TH of the barrier layer BRL may be in a range from about 50 micrometers (μm) to about 150 micrometers (μm). More preferably, the thickness TH of the barrier layer BRL may be in a range from about 75 micrometers (μm) to about 100 micrometers (μm). The closer the tensile modulus of the barrier layer BRL is to the upper limit, the thickness TH of the barrier layer BRL may be thinner, and the closer the tensile modulus of the barrier layer BRL is to the lower limit, the thickness TH of the barrier layer BRL may be thicker. When the thickness TH of the barrier layer BRL is in the above range, the reliability of the display device DD may be improved.

The second adhesive member AM2 may be between the panel protective film LPF and the barrier layer BRL. The second adhesive member AM2 may attach the panel protection film LPF and the barrier layer BRL to each other. For example, the second adhesive member AM2 may overlap the foldable area FA and the non-folding areas NFA1 and NFA2. For example, the second adhesive member AM2 may include an optically clear adhesive, a pressure sensitive adhesive, a photocurable resin, a thermosetting resin, or the like. These can be used alone or in combination with each other. Preferably, the second adhesive member AM2 may include the pressure sensitive adhesive.

The support plate SM may be under the barrier layer BRL. Specifically, the support plate SM may face the second surface of the display panel DP. The support plate SM may serve to support the display panel DP. In addition, the support plate SM may serve to assist in folding the display panel DP. In addition, the support plate SM may prevent foreign substances from entering the display panel DP from outside the display device DD. In addition, the support plate SM may radiate or disperse heat that the display panel DP generates.

At least some portions of the support plate SM may have a rigidity greater than the rigidity of the display panel DP. Accordingly, the support plate SM may prevent deformation of the display panel DP due to a user-applied external force and the like. For example, the support plate SM may include a first support portion SSP1, a second support portion SSP2, and a stretchable portion SP. The stretchable portion SP may be between the first support portion SSP1 and the second support portion SSP2. The stretchable portion SP may overlap the foldable area FA, the first support portion SSP1 may overlap the first non-folding area NFA1, and the second support portion SSP2 may overlap the second non-folding area NFA2. Accordingly, the first and second support portions SSP1 and SSP2 may support the portion of the display panel DP overlapping the first and second non-folding areas NFA1 and NFA2, and the stretchable portion SP may allow and control folding of the display panel DP.

The stretchable portion SP may have elasticity that permits folding and unfolding of the display device DD. However, although FIG. 4 shows only one stretchable portion SP, embodiments of the present disclosure are not necessarily limited thereto. For example, the stretchable portion SP may be formed in multiple pieces. Further description of an embodiment of the stretchable portion SP is provided below.

In an embodiment, the support plate SM may include metal, alloy, and the like. For example, the support plate SM may include stainless steel (SUS), aluminum, copper alloy, magnesium alloy, titanium alloy, and the like. In another embodiment, the support plate SM may include glass or plastic. For example, the support plate (SM) may include carbon fiber reinforced plastic (CFRP), glass fiber reinforced plastic (GFRP), and the like. However, embodiments of the present disclosure are not necessarily limited thereto, and the support plate SM may include various materials.

The third adhesive member AM3 may be between the barrier layer BRL and the support plate SM. The third adhesive member AM3 may attach the barrier layer BRL and the support plate SM to each other. In an embodiment, the third adhesive member AM3 may overlap the foldable area FA and the non-folding areas NFA1 and NFA2. That is, the third adhesive member AM3 may continuously extend across the display area DA. In another embodiment, the third adhesive member AM3 may not overlap the foldable area FA but may overlap the non-folding areas NFA1 and NFA2. That is, the third adhesive member AM3 may include a first portion overlapping the first non-folding area NFA and a second portion overlapping the second non-folding area NFA2, the first portion and the second portion being separated from each other.

The third adhesive member AM3 may include, for example, an optically clear adhesive, a pressure sensitive adhesive, a photocurable resin, a thermosetting resin, and the like. These can be used alone or in combination with each other. In particular, the third adhesive member AM3 may include a pressure sensitive adhesive.

The display device DD as described above can be folded or unfolded, each of the display panel DP. For this folding, the polarizing member POL, the cover window CW, the window protective layer PL, the first, second, and third adhesive members AM1, AM2, and AM3, the panel protective film LPF, the barrier layer BRL, and the support plate SM may be flexible, particularly in the foldable area FA.

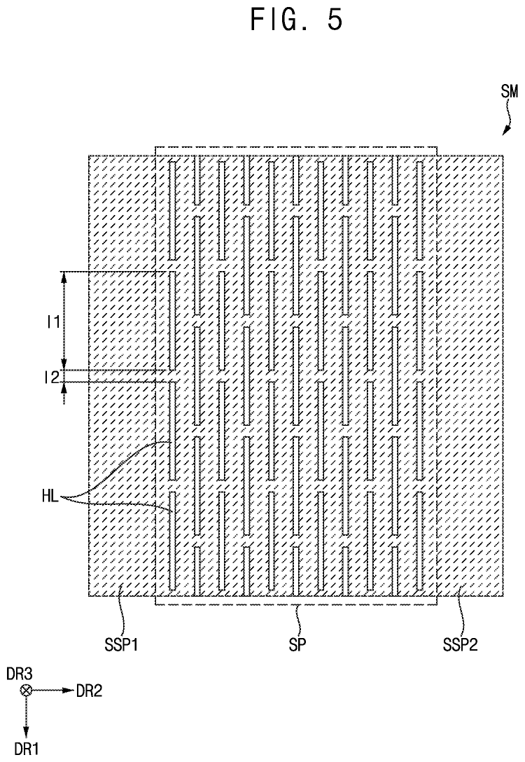

FIG. 5 is a plan view of an embodiment of the support plate SM shown in FIG. 4.

Referring to FIG. 5, the support plate SM may include the first support portion SSP1, the second support portion SSP2, and the stretchable portion SP. In the illustrated embodiment, a plurality of openings HL spaced apart from each other may be defined in the stretchable portion SP of support plate SM. The plurality of openings HL may be formed by removing a portion of the stretchable portion SP, e.g., through an etching process or a punching process. Each of the plurality of openings HL may have an elongated shape extending in the first direction DR1. That is, a long axis of each of the openings HL may be parallel to the first direction DR1.

Each of the openings HL may have substantially the same planar shape. For example, each of the plurality of openings HL may have a rectangular planar shape. However, embodiments of the present disclosure are not necessarily limited thereto, and each of the plurality of openings HL may have various planar shapes.

The openings HL may all have the same length 11. The plurality of openings HL may be arranged in rows that are spaced apart from each other along the first direction DR1 and in columns that are spaced apart from each other along the second direction DR2. In particular, the openings HL in each column may be spaced apart from each other by a predetermined distance 12 along the first direction DR1. The openings HL in the same row may be disposed in parallel with or staggered with the openings HL arranged in an adjacent row. However, embodiments of the present disclosure are not necessarily limited to the illustrated example, and the arrangement of the plurality of openings HL may be changed in various ways.

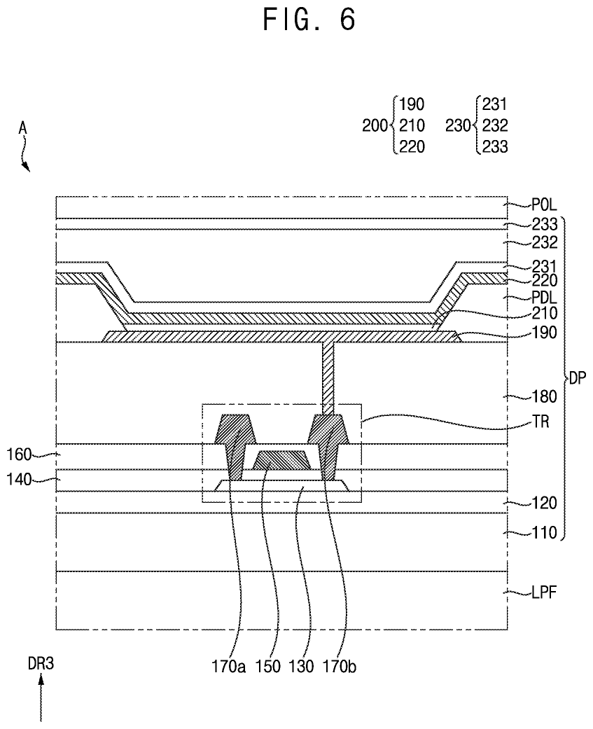

FIG. 6 is an enlarged cross-sectional view of an area A identified in FIG. 4. In particular, FIG. 6 is an enlarged cross-sectional view of a portion of the display panel DP of FIG. 4.

Referring to FIG. 6, the display panel DP may include a substrate 110, a buffer layer 120, a gate insulating layer 140, a transistor TR, an interlayer insulating layer 160, a planarization layer 180, a pixel defining layer PDL, a light emitting element 200, and an encapsulation layer 230. The transistor TR may include an active layer 130, a gate electrode 150, a source electrode 170a, and a drain electrode 170b. The light emitting element 200 may include a lower electrode 190, a light emitting layer 210, and an upper electrode 220, and the encapsulation layer 230 may include a first thin film encapsulation layer 231, a second thin film encapsulation layer 232, and a third thin film encapsulation layer 233.

The panel protective film LPF may be under the substrate 110. The panel protection film LPF may protect a lower portion of the display panel DP.

The substrate 110 may include a transparent material or an opaque material. The substrate 110 may include a flexible transparent resin substrate. An example of a transparent resin substrate that can be used as the substrate 110 may include a polyimide substrate. Alternatively, the substrate 110 may include a quartz substrate, a synthetic quartz substrate, a calcium fluoride substrate, a soda lime glass substrate, an alkali-free glass substrate, and the like. These can be used alone or in combination with each other.

The buffer layer 120 may be on the substrate 110. The buffer layer 120 may prevent metal atoms or impurities from diffusing from the substrate 110 into the transistor TR. For example, the buffer layer 120 may include an inorganic material such as silicon oxide, silicon nitride, and the like. These can be used alone or in combination with each other.

The active layer 130 may be disposed on the buffer layer 120. The active layer 130 may include a metal oxide semiconductor, an inorganic semiconductor (e.g., amorphous silicon or polysilicon), or an organic semiconductor. The active layer 130 may include a source region, a drain region, and a channel region between the source region and the drain region. The source region and the drain region may be doped with impurities (e.g., P-type impurities or N-type impurities), and the channel region may not be doped with impurities.

The gate insulating layer 140 may be on the buffer layer 120. The gate insulating layer 140 may sufficiently cover the active layer 130 on the substrate 110 and may have a substantially flat upper surface without creating steps around the active layer 130. Alternatively, the gate insulating layer 140 may cover the active layer 130 on the substrate 110 and may be disposed along the profile of the active layer 130 with a uniform thickness. The gate insulating layer 140 may include, for example, silicon oxide (SiOₓ), silicon nitride (SiNₓ), silicon carbide (SiCₓ), silicon oxynitride (SiOₓN_{y}), silicon oxycarbide (SiOₓC_{y}), and the like. These can be used alone or in combination with each other.

The gate electrode 150 may be on the gate insulating layer 140. The gate electrode 150 may overlap the channel region of the active layer 130. The gate electrode 150 may include, for example, metal, alloy, metal nitride, conductive metal oxide, transparent conductive material, and the like. These can be used alone or in combination with each other.

The interlayer insulating layer 160 may be on the gate insulating layer 140. The interlayer insulating layer 160 may sufficiently cover the gate electrode 150 on the substrate 110 and may have a substantially flat upper surface without creating steps around the gate electrode 150. Alternatively, the interlayer insulating layer 160 may cover the gate electrode 150 on the substrate 110 and may be disposed along the profile of the gate electrode 150 with a uniform thickness. The interlayer insulating layer 160 may include, for example, silicon oxide, silicon nitride, silicon carbide, silicon oxynitride, silicon oxycarbide, and the like. These can be used alone or in combination with each other.

The source electrode 170a and the drain electrode 170b may be on the interlayer insulating layer 160. The source electrode 170a may be connected to the source region of the active layer 130 through a contact hole penetrating a first portion of the gate insulating layer 140 and the interlayer insulating layer 160, and the drain electrode 170b may be connected to the drain region of the active layer 130 through a contact hole penetrating a second portion of the gate insulating layer 140 and the interlayer insulating layer 160. Each of the source electrode 170a and the drain electrode 170b may include, for example, metal, alloy, metal nitride, conductive metal oxide, transparent conductive material, and the like. These can be used alone or in combination with each other.

The transistor TR including the active layer 130, the gate electrode 150, the source electrode 170a, and the drain electrode 170b may be in the display area DA.

The planarization layer 180 may be disposed on the interlayer insulating layer 160. The planarization layer 180 may sufficiently cover the source electrode 170a and the drain electrode 170b. The planarization layer 180 may include organic materials and/or inorganic materials. In an embodiment, the planarization layer 180 may include an organic material. For example, the planarization layer 180 may include an organic material such as polyimide-based resin, photoresist, polyacryl-based resin, polyimide-based resin, siloxane-based resin, and the like. These can be used alone or in combination with each other.

The lower electrode 190 may be on the planarization layer 180. The lower electrode 190 may be connected to the drain electrode 170b through a contact hole penetrating the planarization layer 180. The lower electrode 190 may include, for example, metal, alloy, metal nitride, conductive metal oxide, transparent conductive material, and the like. These can be used alone or in combination with each other.

The pixel defining layer PDL may be on the planarization layer 180. An opening in the pixel defining layer PDL may overlap and extend to at least a portion of the upper surface of the lower electrode 190. The pixel defining layer PDL may include organic materials and/or inorganic materials. For example, the pixel defining layer PDL may include organic materials such as polyimide-based resin, photoresist, polyacrylic resin, polyamide-based resin, siloxane-based resin, and the like. These can be used alone or in combination with each other.

The light emitting layer 210 may be on the lower electrode 190. The light emitting layer 210 may particularly be on the portion of the lower electrode 190 exposed by the opening in the pixel defining layer PDL. The light emitting layer 210 may contain at least one of light-emitting materials, e.g., a material capable of emitting red light, green light, or blue light. Alternatively, the light emitting layer 210 may include a stack or other combination of light emitting materials capable of generating different color lights, such as red light, green light, and blue light, so that the light emitting layer 210 as a whole emits white light.

The upper electrode 220 may be on the pixel defining layer PDL and the light emitting layer 210. The upper electrode 220 may include, for example, metal, alloy, metal nitride, conductive metal oxide, transparent conductive material, and the like. These can be used alone or in combination with each other.

The light emitting element 200 including the lower electrode 190, the light emitting layer 210, and the upper electrode 220 may be in the display area DA. The light emitting element 200 may be electrically connected to the transistor TR.

The first thin film encapsulation layer 231 may be on the upper electrode 220. The first thin film encapsulation layer 231 may prevent the light emitting layer 210 from being deteriorated or damaged due to penetration of moisture, oxygen, and the like. In addition, the first thin film encapsulation layer 231 may also protect the display panel DP from external shock. The first thin film encapsulation layer 231 may include, for example, one or more flexible inorganic materials.

The second thin film encapsulation layer 232 may be on the first thin film encapsulation layer 231. The second thin film encapsulation layer 232 may improve the flatness of the display panel DP and protect the display panel DP. The second thin film encapsulation layer 232 may include, for example, one or more flexible organic materials.

The third thin film encapsulation layer 233 may be on the second thin film encapsulation layer 232. The third thin film encapsulation layer 233, together with the first thin film encapsulation layer 231, may prevent the light emitting layer 210 from being deteriorated or damaged due to penetration of moisture, oxygen, and the like. In addition, the third thin film encapsulation layer 233 together with the first thin film encapsulation layer 231 and the second thin film encapsulation layer 232 may protect the display panel DP from external shock. The third thin film encapsulation layer 233 may include, for example, one or more flexible inorganic materials.

Referring again to FIGS. 1, 2, 3, 4, 5, and 6, the display device DD according to an embodiment of the present disclosure may include the display panel DP including the flexible foldable area FA and the non-folding areas NFA1 and NFA2 adjacent to the foldable area FA and the barrier layer BRL under the display panel DP and including an elastomer.

The tensile modulus of the barrier layer BRL may be in a predetermined range (e.g., about 0.7 Gpa to about 1.5 Gpa) at a low temperature (−20° C.), and the tensile modulus of the barrier layer BRL may be in a predetermined range (e.g., about 0.4 Gpa to about 1 Gpa) at room temperature. In addition, the thickness TH of the barrier layer BRL may be in a predetermined range (e.g., about 25 micrometers (μm) to about 150 micrometers (μm)). Accordingly, the reliability of the display device DD may be improved.

Hereinafter, the characteristics of embodiments of the present disclosure are compared to some comparative embodiments.

Table 1 provided below shows characteristics of five comparative embodiments and two embodiments in accordance with the present disclosure. In Comparative Embodiment 1, a barrier layer was formed under a display panel using polyimide (PI). In Comparative Embodiment 2, a barrier layer was formed under the display panel using polyethylene terephthalate (PET). In Comparative Embodiments 3, 4, and 5, a barrier layer was formed under the display panel using polyether block amide (PEBA). In Embodiments 1 and 2, the barrier layer BRL was formed under the display panel DP using polyether block amide (PEBA). In Comparative Embodiments 1, 2, 3, 4, and 5, Embodiment 1, and Embodiment 2, the components formed on the display panel and the components formed under the display panel may be common components of a foldable display device known in the art.

Table 1 shows the room temperature modulus, the low temperature modulus, and the thickness of the barrier layer of Comparative Embodiments 1, 2, 3, 4, and 5 and of the barrier layer BRL of Embodiment 1 and Embodiment 2. Here, “room temperature modulus” refers to the tensile modulus at room temperature (i.e., 25° C.), and “low temperature modulus” refers to the tensile modulus at −20° C.

TABLE 1

| | | Room | Low | |
|---|---|---|---|---|
| | | temperature | temperature | |
| | | modulus | modulus | Thickness |
| | Material | (Gpa) | (Gpa) | (μm) |
| Comparative | PI | 5~7 | 7~8 | 20~50 |
| Embodiment 1 | | | | |
| Comparative | PET | 3~5 | 5~6 | 20~50 |
| Embodiment 2 | | | | |
| Comparative | PEBA | 0.04 | 0.89 | 150 |
| Embodiment 3 | | | | |
| Comparative | PEBA | 0.2 | 0.68 | 100 |
| Embodiment 4 | | | | |
| Embodiment 1 | PEBA | 0.4 | 0.89 | 75 |
| Embodiment 2 | PEBA | 0.8 | 1.22 | 75 |
| Comparative | PEBA | 4 or more | 5~6 | 75 |
| Embodiment 5 | | | | |

Table 2 below shows the folding reliability of display devices according to Comparative Embodiments and Embodiments and shows measurements of the repulsion force of the display devices. The folding reliability of the display device was evaluated at −20° C. (i.e., low temperature). To evaluate the folding reliability of the display device, folding and unfolding of the display device were repeated multiple times. In evaluating the folding reliability of the display device, “OK” means that no buckling occurs in the components under the display panel and no cracks occur in the window protective layer.

TABLE 2

| | Folding reliability | Repulsion force (N) |
|---|---|---|
| Comparative Embodiment 1 | Buckling occurs | 4.5 |
| Comparative Embodiment 2 | Buckling occurs | 4.5 |
| Comparative Embodiment 3 | Buckling occurs | 3 or less |
| Comparative Embodiment 4 | Buckling occurs | 3.3 |
| Comparative Embodiment 5 | Crack occurs | 4.5 or more |
| Embodiment 1 | OK | 3.3~3.7 |
| Embodiment 2 | OK | 3.7 |

Referring to Table 2, it can be seen that in Comparative Embodiments 1, 2, 3, and 4, buckling occurred in components under the display panel. In Comparative Embodiment 5, it can be seen that cracks occurred in the window protective layer. On the other hand, in Embodiment 1 and Embodiment 2, it can be seen that buckling does not occur in components under the display panel and no cracks occur in the window protective layer.

Table 2 also indicates that the repulsion forces for the display devices according to Comparative Embodiment 1, Comparative Embodiment 2, and Comparative Embodiment 5 are larger than the repulsion force of the display devices according to Embodiment 1 and

### Embodiment 2

Referring again to FIG. 4, from these results, in the display device DD according to an embodiment of the present disclosure, when the barrier layer BRL includes an elastomer, the tensile modulus of the barrier layer BRL at low temperature (−20° C.) within the range from about 0.7 Gpa to about 1.5 Gpa, the tensile modulus of the barrier layer BRL at room temperature is withing the range from about 0.4 Gpa to about 1 Gpa, and the thickness TH of the barrier layer BRL is in the range from about 25 micrometers (μm) to about 150 micrometers (μm), it can be seen that the folding reliability of the display device DD is excellent at low temperature.

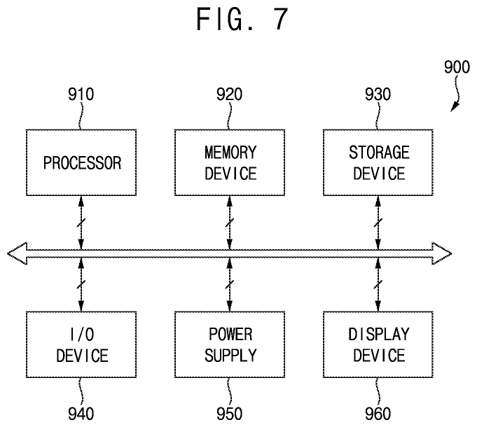

FIG. 7 is a block diagram illustrating an electronic device according to an embodiment of the present disclosure.

Referring to FIG. 7, in an embodiment, an electronic device 900 may include a processor 910, a memory device 920, a storage device 930, an input/output device 940, a power supply 950, and a display device 960. In this case, the display device 960 may correspond to the display device DD described with reference to FIGS. 1 to 6. The electronic device 900 may further include several ports capable of communicating with a video card, a sound card, a memory card, a USB device, and the like.

In an embodiment, the electronic device 900 may be implemented as a television. In another embodiment, the electronic device 900 may be implemented as a smart phone. However, the electronic device 900 is not limited thereto, and for example, the electronic device 900 may be implemented as a mobile phone, a video phone, a smart pad, a smart watch, a tablet PC, a vehicle navigation device, a computer monitor, a laptop computer, a head mounted display (HMD), and the like.

The processor 910 may perform certain calculations or tasks. The processor 910 may control the display device 960. In an embodiment, the processor 910 may be a microprocessor, a central processing unit (CPU), an application processor (AP), and/or the like. The processor 910 may be connected to other components through an address bus, a control bus, a data bus, and the like. The processor 910 may also be connected to an expansion bus, such as a peripheral component interconnect (PCI) bus.

The memory device 920 may store data necessary for the operation of the electronic device 900. For example, the memory device 920 may include an erasable programmable read-only memory (EPROM) device, an electrically erasable programmable read-only memory (EEPROM) device, a flash memory device, a phase change random access memory (PRAM) device, a resistance random access memory (RRAM) device, a nano floating GEe memory (NFGM) device, a polymer random access memory (PoRAM) device, a magnetic random access memory (MRAM) device, a non-volatile memory device such as a ferroelectric random access memory (FRAM) device and/or a volatile memory device such as a dynamic random access memory (DRAM) device, a static random access memory (SRAM) device, and a mobile DRAM device, and the like.

The storage device 930 may include a solid state drive (SSD), a hard disk drive (HDD), a CD-ROM, and the like.

The input/output device 940 may include input means such as a keyboard, keypad, touch pad, touch screen, mouse, and the like and output means such as a speaker, a printer, and the like.

The power supply 950 may supply power necessary for the operation of the electronic device 900. The display device 960 may be connected to other components through buses or other communication links. In an embodiment, the display device 960 may be included in the input/output device 940.

The present disclosure can be applied to various display devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the present disclosure. Accordingly, all such modifications are intended to be included within the scope defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a display panel including a foldable area having flexibility and a non-folding area adjacent to the foldable area;
a cover window on a first side of the display panel; and
a barrier layer on a second side of the display panel opposite to the first side and including an elastomer,
wherein a tensile modulus of the barrier layer is in a range from about 0.7 Gpa to about 1.5 Gpa at −20° C.

2. The display device of claim 1, wherein the tensile modulus of the barrier layer is in a range from about 0.4 Gpa to about 1 Gpa at room temperature.

3. The display device of claim 1, wherein the tensile modulus of the barrier layer at room temperature is in a range from about 25% to about 60% of the tensile modulus at −20° C.

4. The display device of claim 1, wherein the elastomer includes at least one selected from a group consisting of thermoplastic polyurethane (TPU), polyurethane (PU), polyether block amide (PEBA), acrylonitrile-butadiene rubber (NBR), ethylene-propylene rubber (EPDM), silicone rubber, epoxy material, and polyester block copolymer.

5. The display device of claim 1, wherein the barrier layer includes polyether block amide (PEBA).

6. The display device of claim 1, wherein a thickness of the barrier layer is in a range from about 25 micrometers (μm) to about 150 micrometers (μm).

7. The display device of claim 1, further comprising:
a support plate under the barrier layer and facing the second side of the display panel.

8. The display device of claim 7, wherein the support plate includes metal or alloy.

9. The display device of claim 7, wherein the support plate includes carbon fiber reinforced plastic (CFRP) or glass fiber reinforced plastic (GFRP).

10. The display device of claim 7, wherein the support plate includes a stretchable portion overlapping the foldable area.

11. The display device of claim 10, wherein a plurality of openings spaced apart from each other are defined in the stretchable portion.

12. The display device of claim 11, wherein each of the openings has an elongated shape extending in a first direction, and the openings are arranged along the first direction and a second direction crossing the first direction.

13. The display device of claim 7, further comprising:
a panel protective film between the display panel and the barrier layer, the panel protective film including flexible plastic;
a first adhesive member attaching the panel protective film and the barrier layer; and
a second adhesive member attaching the barrier layer and the support plate.

14. The display device of claim 13, wherein the second adhesive member overlaps the foldable area and the non-foldable area.

15. The display device of claim 13, wherein the second adhesive member does not overlap the foldable area and overlaps the non-folding area.

16. A display device comprising:
a display panel including a foldable area having flexibility and a non-folding area adjacent to the foldable area;
a cover window on a first side of the display panel;
a barrier layer on a second side of the display panel opposite to the first side and including an elastomer; and
a support plate under the barrier layer, facing the second side of the display panel, and including a stretchable portion overlapping the foldable area;
wherein a tensile modulus of the barrier layer is in a range from about 0.7 Gpa to about 1.5 Gpa at −20° C., and the tensile modulus of the barrier layer is in a range from about 0.4 Gpa to about 1 Gpa at room temperature.

17. The display device of claim 16, wherein the elastomer includes at least one selected from a group consisting of thermoplastic polyurethane (TPU), polyurethane (PU), polyether block amide (PEBA), acrylonitrile-butadiene rubber (NBR), ethylene-propylene rubber (EPDM), silicone rubber, epoxy material, and polyester block copolymer.

18. The display device of claim 16, wherein a thickness of the barrier layer is in a range from about 25 micrometers (μm) to about 150 micrometers (μm).

19. The display device of claim 16, wherein the support plate includes metal or alloy.

20. The display device of claim 16, further comprising:
a panel protective film disposed between the display panel and the barrier layer, the panel protective film including flexible plastic;
a first adhesive member attaching the panel protective film and the barrier layer; and
a second adhesive member attaching the barrier layer and the support plate.

21. An electronic device comprising:
a display device; and
a processor which controls the display device,
wherein the display device includes:
a display panel including a foldable area having flexibility and a non-folding area adjacent to the foldable area;
a cover window on a first side of the display panel; and
a barrier layer on a second side of the display panel opposite to the first side and including an elastomer, and
wherein a tensile modulus of the barrier layer is in a range from about 0.7 Gpa to about 1.5 Gpa at −20° C.
